(19) United States
(12) Patent Application Publication
(10) Pub. No.: US 2002/0043722 A1
(43) Pub. Date: Apr. 18, 2002

(54) SEMICONDUCTOR DEVICE AND METHOD OF MANUFACTURING THE SAME

(76) Inventor: TETSUYA TAGUWA, TOKYO (JP)

Correspondence Address: SUGHRUE MION ZINN MACPEAK & SEAS, 2100 PENNSYLVANIA AVENUE N W, WASHINGTON, DC, 200373202

(21) Appl. No.: 09/013,034

(22) Filed: Jan. 26, 1998

(30) Foreign Application Priority Data
Jan. 24, 1997 (JP) 011338/97

(51) Int. Cl. H01L 23/48; H01L 23/52; H01L 29/40

(52) U.S. Cl. 257/758

(57) ABSTRACT

A semiconductor device manufacturing method comprising the steps of:

(a) forming an insulating film on a semiconductor substrate on which an element is formed;

(b) selectively removing a predetermined region of the insulating film to form an opening portion so as to expose an underlying conductive layer;

(c) depositing a refractory metal on the opening portion;

(d) depositing refractory metal silicide on the refractory metal deposited on the opening portion; and

(e) filling the opening portion by depositing a refractory nitride metal on the refractory metal silicide deposited on the opening portion.

### BACKGROUND OF THE INVENTION

1. Field of the Invention

The present invention relates to a semiconductor device and a method of manufacturing the same and, more particularly, to a semiconductor device manufacturing method of filling a contact hole and/or a through hole formed in a predetermined region on an insulating interlayer with a refractory metal silicide film and a titanium nitride (TiN) film, or a refractory metal film, a refractory metal silicide film, and a TiN film by the chemical vapor deposition (CVD) method, and a semiconductor device obtained by the manufacturing method.

2. Description of the Prior Art

With an increase in the integration degree of LSIs, contact holes have decreased in size. As a result, the aspect ratio obtained by dividing the depth of a contact hole by the diameter has increased. Since metal films such as aluminum (Al) films formed by the conventional sputtering method exhibit poor step coverage, an increase in connection resistance and disconnection tend to occur.

Even if interconnections can be formed, disconnection tends to occur owing to electromigration, i.e., movement of Al due to currents, posing a problem in terms of reliability. To solve such a problem, a contact hole is filled with a metal.

A typical example of this method is the W plug method of filling a contact hole with a tungsten (W) film formed by the CVD method exhibiting good step coverage. In this method, the adhesion characteristics between titanium (Ti) and W are improved to decrease the connection resistance (contact resistance) of a contact hole, and a barrier metal consisting of TiN is formed to prevent W from entering a substrate. Thereafter, a W film is formed to fill the contact hole by the CVD method, and the entire surface of the W film is etched back to leave the W film only in the contact hole, thereby forming a W plug.

In this method as well, as contact holes decrease in size, and the aspect ratio increases, a Ti or TiN film cannot be formed in a contact hole to a desired thickness by the sputtering method. As a result, the contact resistance increases or an element is destroyed by W.

Attempts have been made to form Ti and TiN films by the CVD method exhibiting good adhesion characteristics. According to this method, however, three layers, i.e., Ti, TiN, and W layers, must be formed by the CVD method, so that the manufacturing step is complicated, and the manufacturing cost increases.

Under the circumstances, a method of filling a contact hole with a TiN film formed by the CVD method exhibiting good step coverage so as to omit the step of forming a W film has been proposed. FIGS. 1A to 1D are sectional views showing a process in this conventional method.

First of all, an insulating interlayer (BPSG) film 62 obtained by doping a silicon oxide film with phosphorus (P) or boron (B) is formed, by the CVD method, on a silicon substrate 61 on which an element are formed. Thereafter, a contact hole reaching the element is formed by the general photolithographic and dry etching techniques (see FIG. 1A). In this case, the diameter of the contact hole is about 0.4 μm.

A Ti film 63 having a thickness of 10 to 50 nm is formed on the resultant structure by the plasma CVD method, and a TiN film 64 having a thickness of about 0.3 μm is formed on the Ti film 63 by the general thermal CVD method, thereby completely filling the contact hole with the Ti and TiN films 63 and 64 (see FIG. 1B).

Subsequently, the Ti and TiN films 63 and 64 on the BPSG film 62 are removed by the dry etching method using chlorine gas to leave the Ti and TiN films 63 and 64 only in the contact hole (see FIG. 1C).

An Al alloy film 65 is deposited on the BPSG film 62 by the sputtering method, and the Al alloy film 65 is patterned into a desired shape by using the lithographic and dry etching techniques, thereby forming an Al interconnection (see FIG. 1D).

Note that the technique of filling a contact hole with a TiN film formed by the CVD method is disclosed in Japanese Unexamined Patent Publication Nos. 5-94964, 5-94969, and 5-136085 and the like.

In the above conventional semiconductor device manufacturing method, when a thick TiN film is formed by the CVD method to fill a contact hole, a large tensile stress of 10 E 10 dyn/cm or more acts on the TiN film. In addition, the adhesion characteristics between the Ti film and the TiN film formed by the thermal CVD method are poor. For these reasons, cracks may be produced in the TiN film or peeling of the film may occur.

If peeling of the TiN film occurs, an underlying BPSG film is excessively etched in the subsequent etching step for the TiN film, resulting in a decrease in manufacturing yield. In addition, a deterioration in reliability occurs. Furthermore, the peeled TiN film acts as a foreign substance to decrease the yield.

If cracks are produced in the TiN film, abnormal etching of the underlying layer and the like occur. In addition, the silicon substrate cracks to destroy the diffusion layer, resulting in an increase in junction leakage current.

### SUMMARY OF THE INVENTION

The present invention has been made in consideration of the above situation in the conventional techniques, and has as its object to provide a semiconductor device manufacturing method of forming a TiN film having a thickness required to fill a contact hole or a through hole by the CVD method while cracking and peeling of the film are prevented, thereby increasing the manufacturing yield and improving the reliability of the product, and a semiconductor device obtained by the manufacturing method.

In order to achieve the above object, according to the first aspect of the present invention, there is provided a semiconductor device manufacturing method comprising the steps of:

(a) forming an insulating film on a semiconductor substrate on which an element is formed;

(b) selectively removing a predetermined region of the insulating film to form an opening portion so as to expose an underlying conductive layer;

(c) depositing a refractory metal on the opening portion;

(d) depositing a refractory metal silicide on the refractory metal deposited on the opening portion; and

(e) filling the opening portion by depositing a refractory nitride metal on the refractory metal silicide deposited on the opening portion.

According to the second aspect of the present invention, the semiconductor device manufacturing method in the first aspect is characterized by further comprising the step of forming a refractory metal, a refractory metal alloy, a refractory metal silicide, and a refractory nitride metal or a low-resistance metal on at least a surface portion of the underlying conductive layer.

According to the third aspect of the present invention, the semiconductor device manufacturing method in the first aspect is characterized by further comprising the step of forming an interconnection layer on the insulating film after removing the refractory nitride metal, the refractory metal silicide, and the refractory metal on a flat portion after the step (e).

According to the fourth aspect of the present invention, the semiconductor device manufacturing method is characterized by further comprising the step of forming a lower capacitance electrode or an interconnection layer on the insulating film after removing the refractory nitride metal, the refractory metal silicide, and the refractory metal deposited on a flat portion after the step (e) in the first aspect.

According to the fifth aspect of the present invention, the semiconductor device manufacturing method is characterized in that the refractory metal in the first aspect is titanium obtained by reducing titanium tetrachloride.

According to the sixth aspect of the present invention, there is provided a semiconductor device comprising a semiconductor substrate on which an element is formed, an insulating film formed on the semiconductor substrate, and an opening portion selectively formed in the insulating film, wherein a refractory metal silicide layer is formed between a refractory metal and a refractory nitride metal layer buried in the opening portion.

According to the seventh aspect of the present invention, the semiconductor device is characterized in that the refractory metal in the sixth aspect is selected from the group consisting of titanium and tungsten.

According to the manufacturing method of the present invention, a refractory metal silicide film is formed on the entire surface between an insulating film formed on a semiconductor substrate by the CVD method and a refractory nitride metal film formed above the refractory metal film by the CVD method. If titanium (Ti) or tungsten (W) is used as a refractory metal, in particular, since the refractory metal silicide film to be grown exhibits excellent adhesion characteristics with respect to these refractory metal films formed on the insulating film by the CVD method, no problem is posed in terms of the adhesion characteristics between the refractory metal film and the refractory nitride metal film. In addition, since the refractory metal silicide film exhibits good adhesion characteristics with respect to the refractory nitride metal film formed by the CVD method, a stress reducing effect can be obtained. Even if, therefore, the refractory nitride metal film is formed relatively thick, the formed refractory nitride metal film can be prevented from cracking or peeling and damaging the diffusion layer.

In addition, since the refractory metal film formed by the CVD method has good step coverage, a refractory metal film having a thickness required to decrease the connection resistance can be formed on the bottom of the opening portion.

Furthermore, since a contact hole or a through hole can be filled with a refractory metal film by the CVD method which can realize a low resistance as compared with the sputtering method, the contact hole or through hole resistance can be set to be low.

The above and many other objects, features and additional advantages of the present invention will become manifest to those versed in the art upon making reference to the following detailed description and accompanying drawings in which preferred embodiments incorporating the principles of the present invention are shown by way of illustrative examples.

### BRIEF DESCRIPTION OF THE DRAWINGS

FIGS. 1A to 1D are sectional views sequentially showing the major steps in a conventional manufacturing method;

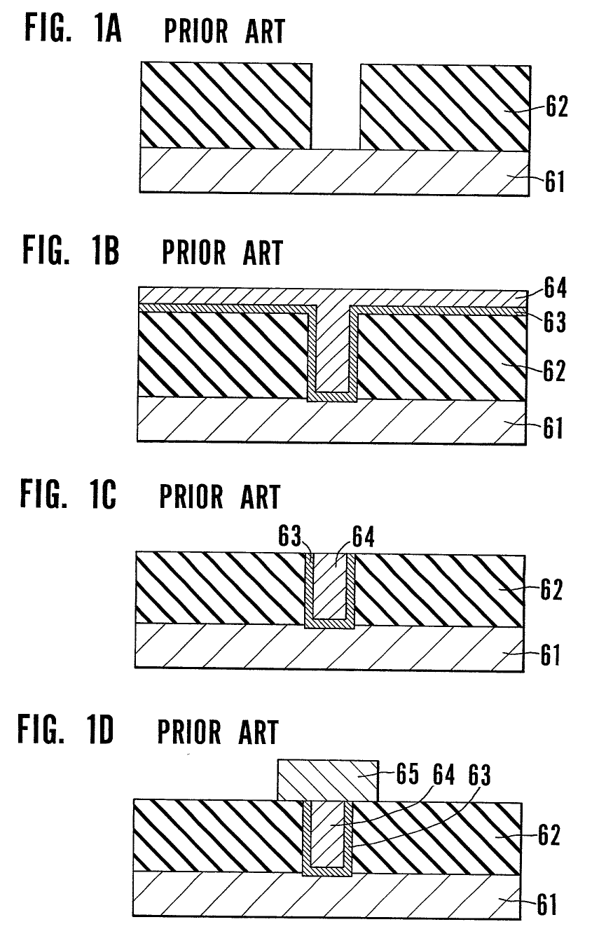

FIGS. 2A to 2F are sectional views sequentially showing the major steps in a manufacturing method according to the first embodiment of the present invention;

FIGS. 3A to 3E are sectional views sequentially showing the major steps in a manufacturing method according to the second embodiment of the present invention;

FIG. 4 is a sectional view showing a major manufacturing step in the third embodiment of the present invention; and

FIGS. 5A to 5F are sectional views sequentially showing the major steps in a manufacturing method according to the fourth embodiment of the present invention.

### DETAILED DESCRIPTION OF THE PREFERRED EMBODIMENTS

Several preferred embodiments of the present invention will be described below with reference to the accompanying drawings.

[First Embodiment]

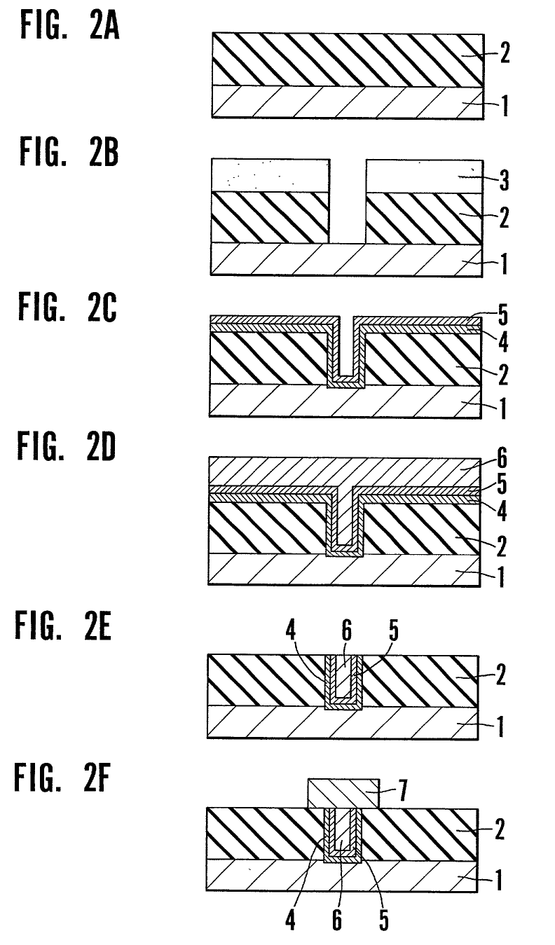

FIGS. 2A to 2D are sectional views sequentially showing the major steps in a manufacturing method according to the first embodiment of the present invention.

A BPSG film 2 having a thickness of about 1.5 μm is formed as an insulating interlayer, by the CVD method, on a silicon substrate 1 on which an element is formed (see FIG. 2A). The BPSG film 2 is then coated with a photoresist film 3. Thereafter, an opening portion having a size of about 0.3 μm is formed at a desired position by exposure/development, and the BPSG film 2 is etched by dry etching using the photoresist film 3 as a mask and a gas mixture of trifluoromethane (CHF₃) and carbon monoxide (CO) gas until the silicon substrate 1 is exposed, thereby forming a contact hole (see FIG. 2B).

After the photoresist film 3 is removed, a Ti film 4, a titanium silicide film 5, and a TiN film 6 are sequentially formed on the entire surface of the wafer by the CVD method. The Ti film 4 is formed to have a thickness of 10 to 30 nm by the CVD method of generating a plasma by feeding titanium tetrachloride gas (TiCl₄), argon gas (Ar), and hydrogen gas (H₂) at 3 to 10 sccm, 200 to 500 sccm, and 1,000 to 2,000 sccm, respectively, setting the pressure to 3 to 10 Torr, and heating the silicon substrate 1 to 450 to 600° C., and applying an RF power of several 100 W to the counter electrode of the substrate. The titanium silicide film 5 is then formed by doping the resultant structure with silane (SiH₄) at 10 to 50 sccm (see FIG. 2C).

The TiN film is formed to have a thickness of 0.2 to 0.3 μm by the thermal CVD method of feeding ammonia gas (NH₃) and nitrogen gas (N₂) at 40 to 70 sccm and 30 to 50 scam, respectively, setting the pressure to 15 to 30 Torr, and heating the silicon substrate 1 to 400 to 500° C., thereby filling the contact hole with the TiN film (FIG. 2D).

The entire surface of the resultant structure is etched by chlorine gas (Cl₂) to remove the TiN film 6, the titanium silicide film 5, and the Ti film 4 on the flat portion so as to expose the surface of the BPSG film 2. As a result, these films are left only in the contact hole (see FIG. 2E).

An Al alloy film 7 is formed to have a thickness of 0.3 to 1.0 μm by the sputtering method. The Al alloy film 7 is then patterned into a desired shape by the general lithographic and dry etching techniques, thereby forming an Al interconnection (see FIG. 2F).

The function and effect of this embodiment will be described below.

Since the titanium silicide film 5 is formed under the TiN film 6 formed by the CVD method, the adhesion characteristics of the TiN film 6 are better than those of the Ti film 4 formed by the CVD method. In addition, since the silicide film 5 can absorb the stress on the TiN film 6, even if the TiN film 6 is formed thick, cracking and peeling do not occur. The contact hole can therefore be filled with the Ti film 4 having good step coverage while cracking and peeling are prevented.

In addition, according to this embodiment, the contact hole is filled with the Ti film 4, the titanium silicide film 5, and the TiN film 6, which are formed by the CVD method. Even a contact hole having a high aspect ratio can therefore be filled, and an interconnection that can realize a low connection resistance on the silicon substrate can be easily formed on the bottom of the contact hole.

[Second Embodiment]

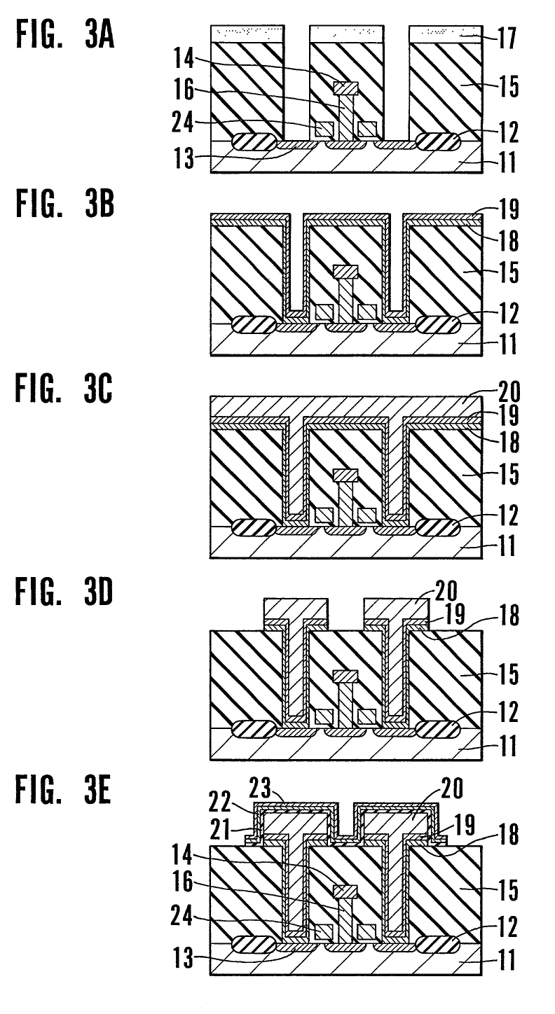

FIGS. 3A to 3E are sectional views sequentially showing the major steps in a manufacturing method according to the second embodiment of the present invention. In this embodiment, a TiN film formed by the CVD method is used as a capacitance electrode.

A silicon oxide film 12 for element isolation is formed on the surface of a P-type silicon substrate 11. An N-type impurity is doped into the resultant structure by using the silicon oxide film 12 as a mask to form a bit line 14 consisting of W silicide or the like and connected to one of N-type diffusion layers 13 in a surface region of the P-type silicon substrate 11. A silicon oxide film 15 such as a BPSG film is formed by the CVD method to cover the entire surface of the resultant structure. Thereafter, as in the above embodiment, a contact hole having a diameter of about 0.2 μm and reaching the surface of the N-type diffusion layer 13 is formed at a desired position on the silicon oxide film 15 by using the lithographic and dry etching techniques (see FIG. 3A).

A photoresist film 17 is then removed, and a native oxide film on the bottom of the contact hole is removed by a 1% hydrogen fluoride (HF) aqueous solution. Thereafter, a Ti film 18 having a thickness of 10 to 30 nm and a titanium silicide film 19 having a thickness of 10 to 50 nm are formed by the plasm CVD method (see FIG. 3B).

Subsequently, a TiN film 20 having a thickness of 0.6 to 1.0 μm is formed by the thermal CVD method (see FIG. 3C). The formation conditions for the Ti film 18, the titanium silicide film 19, and the TiN film 20 are the same as those in the first embodiment.

The TiN film 20, the titanium silicide film 19, and the Ti film 18 are patterned into a desired shape by using the general lithographic and dry etching techniques, thereby forming a lower capacitance electrode (see FIG. 3D).

Subsequently, a tantalum oxide film (Ta₂O₅ film) 21, a TiN film 22, and a W silicide film 23 are formed to have thicknesses of about 10 nm, 100 nm, and 100 nm, respectively. The Ta₂O₅ film 21 is formed by the CVD method using ethoxytantalum and oxygen gases as reaction gases under the following conditions, for example: pressure=1 Torr and substrate temperature=450° C. The TiN film 22 and the W silicide film 23 are formed by the sputtering method.

The W silicide film 23, the TiN film 22, and the Ta₂O₅ film 21 are then patterned by the photolithographic and dry etching techniques, thereby forming a cell plate electrode (see FIG. 3E).

In this embodiment, the thick TiN film 20, the titanium silicide film 19, and the Ti film 18 are formed by the CVD method. Even if, however, these films are patterned into a micorpatterned electrode having a size of about 0.2 μm×0.4 μm, no peeling occurs because the titanium silicide film exhibiting good adhesion characteristics with respect to both the Ti film and the TiN film is formed.

[Third Embodiment]

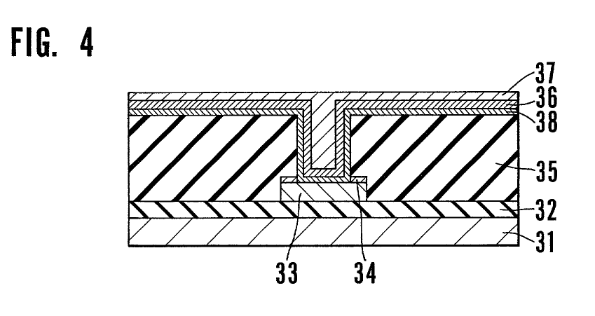

FIG. 4 is a sectional view showing the major step in the third embodiment of the present invention. In this embodiment, a through hole is formed above an interconnection made of an Al alloy film.

A silicon oxide film 32 is formed on a silicon oxide film 32 on which an element is formed. A 0.5-μm thick Al alloy film 33 is formed on the silicon oxide film 32 by the sputtering method. A TiN film 34 having a thickness of 25 to 50 nm is formed as an antireflection film on the Al alloy film 33 by the sputtering method. Thereafter, the above films are patterned into a lower interconnection by using the photolithographic and dry etching techniques.

A silicon oxide film 35 is deposited on the resultant structure by the CVD method. The silicon oxide film 35 is then selectively removed by using the photolithographic and dry etching techniques. As a result, a through hole having a diameter of about 0.25 μm is formed to expose the surface of the Al alloy film 33.

A Ti film 38 having a thickness of 5 to 50 nm is formed by the plasma CVD method using TiCl₄, H₂, and Ar. A titanium silicide film 36 having a thickness of 10 to 50 nm is also formed by doping the Ti film 38 with SiH₄.

A TiN film 37 having a thickness of 0.2 to 0.3 μm is formed by the thermal CVD method using TiCl₄, NH₃, and N₂, thus filling the through hole with the TiN film 37 (see FIG. 4).

The TiN film, the titanium silicide film, and the Ti film are etched until the surface of the silicon oxide film 35 is exposed, and the TiN film is left only in the through hole. Thereafter, an Al film is deposited and patterned to form an upper interconnection (not shown).

In this embodiment, the Al alloy film is formed on the bottom of the through hole. However, an interconnection made of a refractory metal, a refractory silicide, copper, gold, or the like may be formed instead of the Al alloy film.

[Fourth Embodiment]

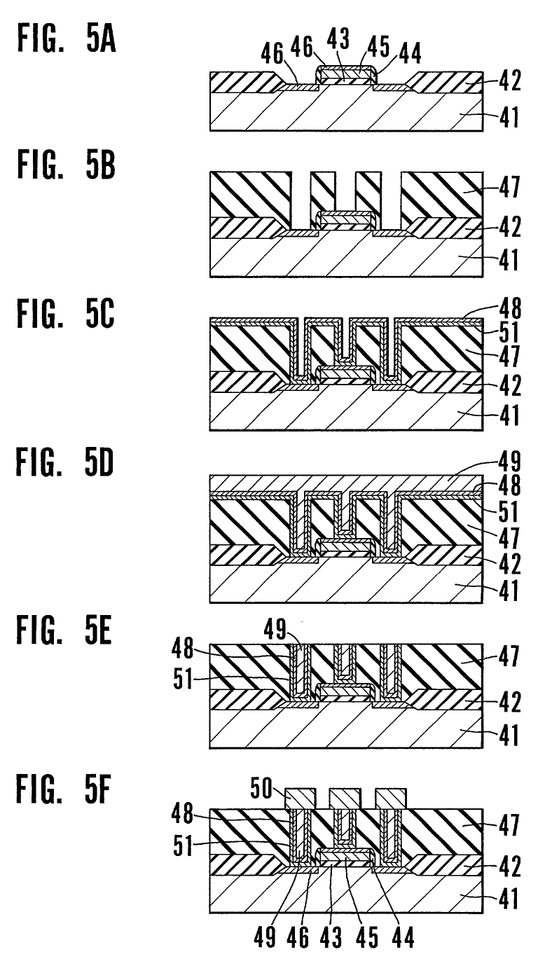

FIGS. 5A to 5F are sectional views sequentially showing the major steps in a manufacturing method according to the fourth embodiment of the present invention.

A thin silicon oxide film 43 serving as a gate oxide film is formed in a region, on a silicon substrate 41, which is isolated by a silicon oxide film 42. A polysilicon film 45 serving as a gate electrode is formed on the silicon oxide film 43.

After the side surfaces of the polysilicon film 45 are covered with a silicon oxide film 44, a Ti film is formed by the sputtering method. The resultant structure is then annealed at 600 to 800° C. for 30 to 60 seconds to form titanium silicide films 46 on the portions, of the silicon substrate 41 and the polysilicon film 45, which are in contact with the Ti film. The remaining portions of the Ti film are removed by NH₃ and a hydrogen peroxide solution, thereby forming a transistor having a so-called salicide structure (see FIG. 5A).

A BPSG film 47 having a thickness of about 1.5 μm is formed on the resultant structure by the CVD method. A contact hole reaching the titanium silicide film 46 is formed at a desired position on the BPSG film by the photolithographic and dry etching techniques (see FIG. 5B).

A 10-nm thick Ti film 51 and a 20-nm thick titanium silicide film 48 are then formed on the resultant structure by the plasma CVD method (see FIG. 5C).

Subsequently, a TiN film 49 having a thickness of 0.2 to 0.3 μm is formed on the resultant structure by the thermal CVD method using TiCl₄, NH₃, and N₂, thereby filling the contact hole with the TiN film 49 (see FIG. 50).

The TiN film 49, the titanium silicide film 48, and the Ti film 51 are etched by reactive ion etching using a chlorine-based gas such as Cl₂ gas until the BPSG film 47 is exposed, thereby leaving the titanium silicide film and the TiN film in only the contact hole (see FIG. 5E).

Subsequently, an Al alloy film 50 is formed on the BPSG film 47 by the sputtering method, and is patterned into a desired shape by the general lithographic and dry etching techniques, thereby forming an Al interconnection (see FIG. 5F).

In this embodiment, although the titanium silicide film 46 is formed on the bottom of the contact hole in advance, the Ti film is formed by the CVD method. This process is performed to reduce the native oxide film on the titanium silicide film with Ti. By this method, a low contact resistance can be obtained.

What is claimed is:

1. A semiconductor device manufacturing method comprising the steps of:
(a) forming an insulating film on a semiconductor substrate on which an element is formed;
(b) selectively removing a predetermined region of the insulating film to form an opening portion so as to expose an underlying conductive layer;
(c) depositing a refractory metal on the opening portion;
(d) depositing refractory metal silicide on the refractory metal deposited on the opening portion; and
(e) filling the opening portion by depositing a refractory nitride metal on the refractory metal silicide deposited on the opening portion.

2. A method according to claim 1, further comprising the step of forming a refractory metal, a refractory metal alloy, a refractory metal silicide, and a refractory nitride metal or a low-resistance metal on at least a surface portion of the underlying conductive layer.

3. A method according to claim 1, further comprising the step of forming an interconnection layer on the insulating film after removing the refractory nitride metal, the refractory metal silicide, and the refractory metal on a flat portion after the step (e).

4. A method according to claim 1, further comprising the step of forming a lower capacitance electrode or an interconnection layer on the insulating film after removing the refractory nitride metal, the refractory metal silicide, and the refractory metal deposited on a flat portion after the step (e).

5. A method according to claim 1, wherein the refractory metal is titanium obtained by reducing titanium tetrachloride.

6. A semiconductor device comprising a semiconductor substrate on which an element is formed, an insulating film formed on said semiconductor substrate, and an opening portion selectively formed in said insulating film, wherein a refractory metal silicide layer is formed between a refractory metal and a refractory nitride metal layer buried in said opening portion.

7. A semiconductor device according to claim 6, wherein said refractory metal is selected from the group consisting of titanium and tungsten.

8. A semiconductor device comprising a semiconductor substrate on which an element is formed, an insulating film formed on said semiconductor substrate, and an opening portion selectively formed in said insulating film, and obtained by the manufacturing method defined in any one of claims 1 to 5.
